(19) United States
(12) Patent Application Publication
(10) Pub. No.: US 2026/0040504 A1
(43) Pub. Date: Feb. 5, 2026

(54) OPTIMIZED EVAPORATIVE DRY COOLING ARRANGEMENT AND PROCESS FOR A DATACENTER

(71) Applicant: OVH, Roubaix (FR)

(72) Inventors: Ali CHEHADE, Moncheaux (FR); Mohamad HNAYNO, La Madeleine (FR)

(21) Appl. No.: 19/288,007

(22) Filed: Aug. 1, 2025

(30) Foreign Application Priority Data
Aug. 2, 2024 (EP) 24306313.8

(51) Int. Cl. H05K 7/20; G01M 3/16

(52) U.S. Cl. CPC H05K 7/20827; H05K 7/20327; H05K 7/20836; G01M 3/16

(57) ABSTRACT

A datacenter dry cooling system and method for cooling a heat-generating source are provided and directed to maximizing the absorption of cooling water applied to an evaporating pad for evaporation and ambient air cooling while eliminating any leakages. The evaporating pad is disposed on an air-to-liquid heat exchanger panel supplied by an evaporating cooling water distribution arrangement for applying the controlled amount of cooling water to the evaporating pad. The applied cooling water is to be completely evaporated while being exposed to ambient airflow to dissipate the thermal energy of the heat-generating sources. The evaporating pad includes corresponding temperature and/or humidity sensors for detecting temperature/humidity levels at an air outlet surface and a temperature and humidity sensor at an air inlet surface. A controller coupled to the temperature and humidity sensors and evaporating cooling water arrangement controls the cooling water volume flow based on the detected temperature and humidity.

### CROSS-REFERENCE

The present application claims priority to European Patent Application No. 24306313 filed on Aug. 2, 2024, and entitled “OPTIMIZED EVAPORATIVE DRY COOLING ARRANGEMENT AND PROCESS FOR A DATACENTER”, the entirety of which is incorporated herein by reference.

### FIELD

The present technology generally relates to the field of datacenter cooling measures and, in particular, to an evaporative cooling arrangement for a dry cooling system.

### BACKGROUND

Dry coolers and other heat exchanger systems operate to dissipate thermal energy from a cooling fluid (e.g., water) circulating therethrough to the ambient environment. For example, in a datacenter, a dry cooler can be used to cool heated water extracted from within the datacenter (e.g., water circulated through water blocks coupled to heat-generating electronic components).

In order to improve the efficiency of heat exchanger systems, some arrangements implement direct spray evaporative techniques to precool the temperature of the ambient air that flows through the heat exchanger system. For example, in some cases, a water spraying system (i.e., an atomizer) is placed at the air inlet of a dry cooler to spray water and increase the humidity level of the ambient air, thereby reducing its temperature. Other adiabatic cooling implementations also include for instance, evaporating pads in which water is applied to ambient air prior to entering the heat exchanger system or evaporating pads in which water is applied directly thereon.

However, in use, these implementations have experienced some drawbacks. For instance, these implementations typically employ a multitude of sensors, detectors, hardware, valves, and electronic components to control the water flow. Also, using direct spray techniques may consume a large volume of water, which negatively impacts the Water Usage Effectiveness (WUE) of such techniques and may also promote the dispersion of pathogenic bacteria, such as Legionella. Additionally, not all the water applied to the evaporating pads is absorbed and dissipated into the ambient air, thereby resulting in inconsistent cooling, temperature fluctuations, dust/contaminant buildup, and increased energy and water consumption to rectify these issues.

Therefore, even though the cooling implementations and techniques noted above provide certain benefits, further improvements that alleviate at least some of the drawbacks of these cooling implementations/techniques are still desirable.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology have been developed based on certain drawbacks associated with conventional dry cooling techniques and implementations.

In one aspect of the present technology, there is provided a datacenter dry cooling process for cooling a heat-generating electronic processing source, the datacenter associated with a dry cooler unit that incorporates an air-to-liquid heat exchanger panel, an evaporating pad, and an evaporating cooling water distribution arrangement for applying cooling water to the evaporating pad, in which the method comprises: providing, at an air outlet surface of the evaporating pad, at least one temperature sensor for detecting temperature levels and/or at least one relative humidity sensor for detecting humidity levels; providing, at an air inlet surface of the evaporating pad, at least one temperature sensor and/or relative humidity sensor for detecting temperature levels and/or humidity levels on an air inlet surface of the evaporating pad; providing at least one sensor for detecting a leak from the evaporating pad; and providing a controller that is communicatively-coupled to the temperature and humidity levels sensors disposed at the air outlet and air inlet surfaces of the evaporating pad, the leak sensor, and the evaporating cooling water distribution arrangement.

In a related aspect of the present technology, the controller is configured to execute instructions for: receiving the detected temperature and humidity levels from the sensors disposed at the air outlet and air inlet surfaces of the evaporating pad and the leak sensor; determining whether a first detected temperature level from the air outlet surface is greater than a predetermined first threshold temperature value and, upon determining that the detected first temperature level is greater than the first threshold temperature value, adjusting a predetermined target volume flow rate of the evaporating cooling water distribution arrangement to a predetermined maximum flow rate; determining whether a second detected temperature level from the air outlet surface is greater than a second threshold temperature value and, upon determining that the detected temperature level is greater than the second threshold temperature value, adjusting the predetermined the target volume flow rate of the evaporating cooling water distribution arrangement to the predetermined maximum flow rate; and determining whether the second detected temperature level is less than a third threshold temperature value and, upon determining that the second detected temperature level is less than the third threshold temperature value, adjusting the predetermined the target volume flow rate of the evaporating cooling water distribution arrangement to a predetermined minimum flow rate.

In another related aspect of the present technology, the datacenter dry cooling process further comprises controlling a volume flow valve of the evaporative cooling water distribution arrangement for applying a controlled measured flow rate of the cooling water to the evaporating pad, by: determining whether a detected flow rate is greater than the recommended volume flow rate and, upon determining that the detected flow rate is greater than the recommended volume flow rate, adjusting the volume flow rate to a reduced level that is less than the detected flow; determining whether the reduced volume flow rate is less than the predetermined minimum flow rate and, upon determining that the reduced volume flow rate is less than the predetermined minimum flow rate, adjusting the volume flow rate to the predetermined minimum flow rate; determining whether the detected flow rate is less than the recommended volume flow rate and, upon determining that the detected flow rate is less than the recommended volume flow rate, adjusting the volume flow rate to an increased level that is greater than the detected flow rate; determining whether the increased volume flow rate level results in an opened state of the volume flow valve and, upon determining that the volume flow valve is in an open state, send an alert message indicating that the volume flow valve is in an open state but there exists an insufficient flow rate.

Within the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task at hand.

Additionally, within the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

Relatedly, within the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned object and/or aspects, but may not, necessarily include all of them.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1A illustrates a conceptual representation of a dry cooler unit, in accordance with the nonlimiting embodiments of the present technology;

FIG. 1B illustrates a high-level functional block general overview diagram of a dry cooling arrangement, in accordance with the nonlimiting embodiments of the present technology;

FIG. 2A illustrates an evaporative cooling water distribution arrangement, in accordance with the nonlimiting embodiments of the present technology;

FIG. 2B illustrates a cross-sectional view of an evaporative cooling pad and various sensors, in accordance with the nonlimiting embodiments of the present technology;

FIG. 3 illustrates a functional flow diagram providing the processing operations for adjusting the volume flow of the evaporative cooling water based on detected temperature values for the evaporative cooling water distribution arrangement of FIG. 2A, in accordance with non-limiting embodiments of the present technology;

FIG. 4A illustrates a functional flow diagram providing the processing operations for controlling a volume flow valve of the evaporative cooling water distribution arrangement of FIG. 2A, in accordance with non-limiting embodiments of the present technology;

FIG. 4B illustrates a functional flow diagram providing processing operations directed to discerning any required flow rate issues after fully opening the volume flow valve, in accordance with non-limiting embodiments of the present technology;

FIG. 5 illustrates a functional block diagram of monitoring controller 500 configured to execute various processing operations, in accordance with an embodiment of the present technology;

FIG. 6A illustrates a graph of temperature levels in accordance with an embodiment of the present technology; and

FIG. 6B illustrates a graph of humidity levels in accordance with an embodiment of the present technology.

It should be appreciated that, unless otherwise explicitly specified herein, the figures are not drawn to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes that may be substantially represented in non-transitory computer-readable media and so executed by a computer or processor, whether or not such computer or processor is explicitly shown.

The functions of the various elements shown in the figures including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

With this said, attention is directed to some non-limiting examples to illustrate various implementations of aspects of the present technology.

In the non-limiting disclosed embodiments of the present technology detailed below, a datacenter dry cooling system directed to cooling heat-generating electronic processing assemblies is presented. The dry cooling system incorporates an evaporating cooling water distribution arrangement for supplying evaporative cooling water to an evaporating pad of the dry cooling system. The dry cooling system further incorporates relatively humidity and/or temperature sensors to detect outside external ambient conditions as well as an electronic monitoring controller configured to control and provide the optimal volume flow of the evaporative cooling water applied to the evaporating pad based, at least in part, on the data provided by the temperature sensors and humidity sensors. In this manner, the disclosed embodiments provide an evaporative cooling water arrangement for a datacenter dry cooler unit that optimally controls the application of cooling water to evaporating pads to virtually prevent any cooling water leakages while, at the same time, substantially reducing the number of sensors, detectors, hardware, valves, and electronic components typically required by the prior art configurations to achieve the intended effect. This dry cooling arrangement further provides the added benefit of using an optimal amount of water to reduce large water consumption as well as achieve virtually 100% evaporation ratio with no water leakage.

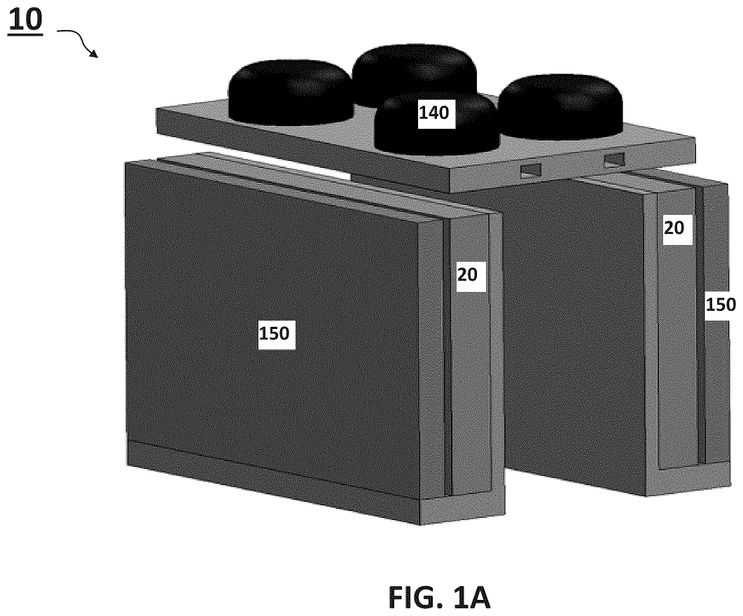

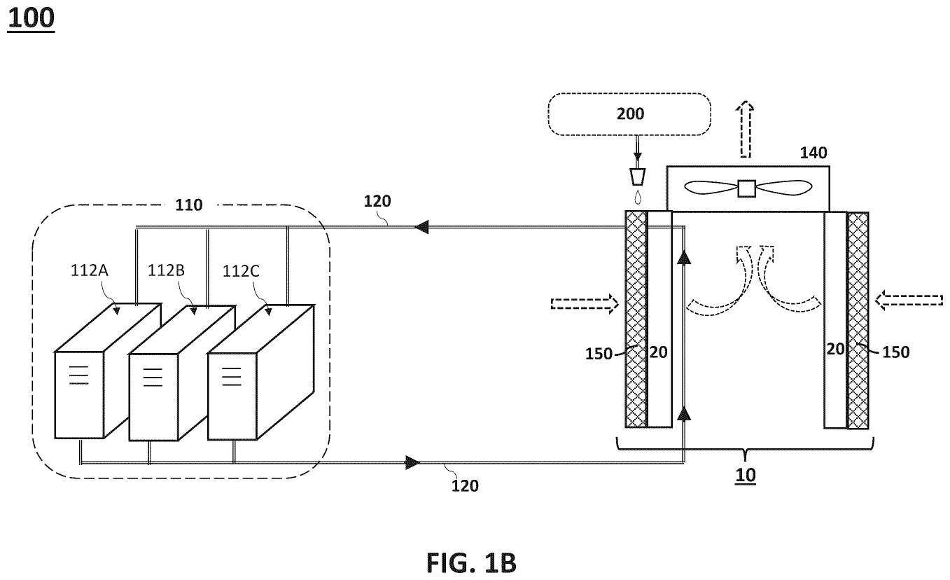

Accordingly, FIG. 1A illustrates a conceptual representation of a dry cooler unit 10 and FIG. 1B illustrates a high-level functional block general overview diagram of a dry cooling arrangement 100, in accordance with the nonlimiting embodiments of the present technology. The dry cooler unit 10 may be located on any suitable support surface, such as, for example, the roof of a datacenter building or stable surface in close proximity to the datacenter. As shown, dry cooler unit 10 generally comprises the basic following components: at least one heat exchanger panel 20, at least one fan assembly 140, and at least one evaporating pad 150.

The heat exchanger panel 20 operates to expel heated thermal energy of a cooling liquid, flowing through and warmed by rack-mounted heat-generating electronic processing assemblies, into the ambient environment. That is, the heat exchanger panel 20 is configured as a liquid-to-air heat exchanger, having an air inlet side (not shown) for receiving ambient air flow and an air outlet side (not shown) for expelling heated air. The heat exchanger panel 20 also incorporates cooling coils (not shown), in which warmed cooling liquid circulates therethrough via a cooling liquid closed loop 120.

As indicated in FIG. 1B, the cooling liquid closed loop 120 conveys the cooling liquid to processing servers 112A-C(collectively referred to as “heat source 110”) that house the rack-mounted heat-generating electronic processing assemblies (not shown). The cooling liquid is supplied to liquid cooling blocks (not shown) in direct thermal contact to the heat-generating electronic processing components for cooling purposes. The cooling liquid absorbs the generated heat and the warmed cooling liquid is circulated, via the cooling liquid closed loop 120 back to the dry cooler unit 10 for extracting and dissipating the thermal energy therein and recooling the cooling fluid. It will be appreciated that the cooling liquid may comprise water, dielectric fluid, refrigerant fluid, diphasic fluid, or any other fluid suitable for collecting and discharging thermal energy.

The fan assembly 140 is disposed on an upper surface of the dry cooler unit 10 and is configured to forcibly cause ambient air flow throughout the dry cooler 10. The fan assembly 140 comprises a plurality of fans located at an upper end of the dry cooler unit 10. The fan assembly 140 includes respective motors (not shown) that drive each of the fans to rotate and forcibly pull ambient air from a lateral side of the dry cooler 10 towards an interior space of the dry cooler unit 10. The heat exchanger panel 20 (and respective cooling coils) is exposed to the forcibly pulled-in ambient air. In turn, the thermal energy manifested by the warmed first cooling liquid circulating through the cooling coils is transferred, via the outlet side, and expelled vertically upwards from the dry cooler unit 10 into the ambient environment.

The evaporating pad 150 is positioned to directly abut an outer lateral surface of the heat exchanger panel 20. The evaporating pad 150 is configured to absorb a cooling liquid applied thereto while enabling air flow to pass through the pad surface. The evaporating pad 150 comprises an air inlet surface (not shown) for receiving the air flow and an air outlet surface (not shown) for expelling the air flow. The evaporating pad 150 may be made of plastic material, cellulose, glass fibers, etc. to absorb the applied cooling liquid.

As will be described in greater detail below, the evaporating pad 150 operates to receive cooling water from an evaporative cooling water distribution arrangement 200. The evaporative cooling arrangement 200 is configured to apply a specifically-controlled measured amount of evaporative cooling water, based on certain detected operational factors, to wet the evaporating pad 150 for optimal cooling performance while virtually eliminating any water leakages.

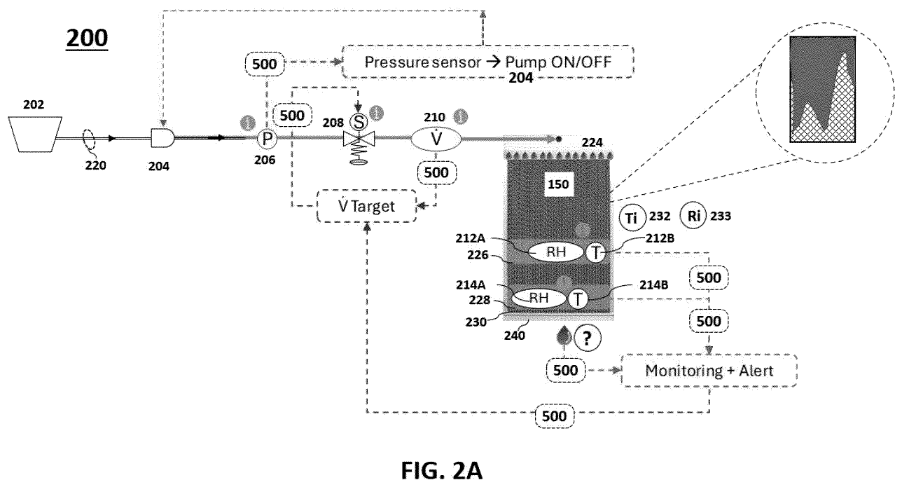

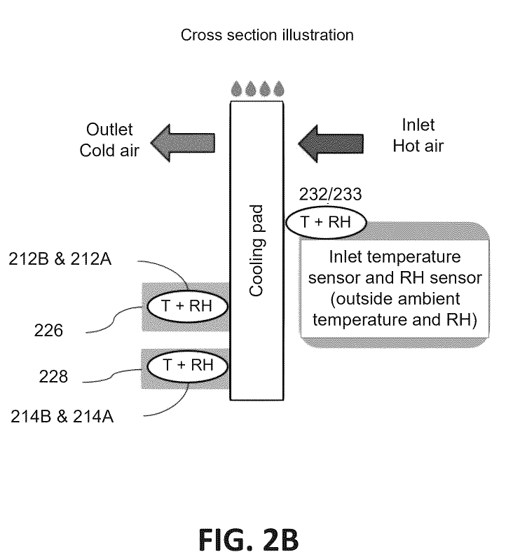

To this end, FIGS. 2A and 2B illustrate an evaporative cooling water distribution arrangement 200, in accordance with the nonlimiting embodiments of the present technology. The evaporative cooling water is supplied by source 202 via a distribution conduit 220 and a pump 204. The pump 204 is configured to forcibly urge the flow of the evaporative cooling water throughout the distribution conduit 220. It will be appreciated that the evaporative cooling water supplied by source 202 may comprise deionized water, osmosed water, or any other type of treated/processed water that is free from minerals or contaminants.

The pressure level of the flow of the evaporative cooling water is detected by pressure sensor 206. As will be described in greater detail below, pressure sensor 206, humidity sensors 212A, 214A, 233, temperature sensors 212B, 214B, 232 and flow-rate sensor 210 are communicative-coupled to a monitoring controller 500 to report the respective detected water pressure data, relative humidity data, temperature data, and water flow data. The monitoring controller 500 is configured to process the data to determine whether the operations of certain components should remain the same, be subjected to adjustments, or turned off.

Provided that the pump 204 is allowed to continue operations, the distribution conduit 220 conveys the evaporative cooling water to a volume flow control valve 208. The flow control valve 208 may comprise a solenoid-controlled valve, a pressure independent control valve (PICV), or an automatic balancing pressure control valve (ABQM). In an alternative configuration, a temperature sensor (not shown) may be incorporated before or after the control valve 208 to detect the temperature levels of the supplied water and may also be communicatively-coupled to the controller 500. In this manner, if the temperature sensor detects that the temperature of the supplied water is “very low” the supplied water may be integrated with the cooling liquid closed loop 120 via a plate heat exchanger to lower the inlet water temperature to the dry cooler unit 10 and reduce the cooling demand. In other words, the low temperature of the water supplied to the cooling pads can be exploited to reduce the outlet temperature of the data center, thereby decreasing the cooling demand.

The distribution conduit 220 subsequently conveys the evaporative cooling water to a water distribution unit 224 configured to apply the cooling water to the evaporating pad 150. The water distribution unit 224 may comprise a nozzle or a series of nozzles, a fluid discharge manifold, a sprayer, or any structure that uniformly dispenses the cooling water across the width dimension of a top surface of the pad 150.

For purposes of illustration, the depicted embodiment indicates that the evaporating pad 150 is associated with humidity sensors 212A, 214A and/or temperature sensors 212B, 214B on the air outlet surface that measure the outside relative humidity and temperature levels that measures the temperature levels after the evaporative cooling pad. In various implementations, the evaporating pad 150 may be associated with only temperature sensors and only humidity sensors on the air outlet surface of the pad 150 or as will be described in greater detail below, a temperature sensor associated with a first band across the pad surface and a humidity sensor associated with a second band across the pad surface. In addition, there is provided an inlet temperature sensor 232 and inlet humidity sensor 233 that respectively measure the outside temperature and humidity levels before the evaporative cooling pad. Therefore, it should be appreciated that such alternative implementations are consistent with the scope of the disclosed concepts.

Returning to the illustrated embodiment of FIG. 2A, the air inlet and outlet surfaces of the evaporating pad 150 may implement a first monitoring band 226 across the width dimension of the evaporating pad 150 and a second monitoring band 228 across the width dimension of the evaporating pad 150 that is positioned lower than the first band 226 at the outlet surface of the evaporating pad 150. By way of relative reference, the first monitoring band 226 is disposed below a halfway point of the evaporating pad 150 vertical dimension and the second monitoring band 228 is disposed below the first monitoring band 226 such that a spaced buffer band 230 is defined between the bottom of the second band 228 and the bottom surface of the evaporating pad 150. The spaced buffer band 230 operates as an internal reservoir that absorbs any residual cooling water, via capillary action, from the bottom of the evaporating pad 150 that may otherwise result in leakages.

The relative positioning of the first and second monitoring bands 226, 228 noted above is based on the developer's observation that, while the cooling water is applied uniformly, the actual absorption of the cooling water is nonuniform throughout the evaporating pad 150. That is, as conceptually represented in the circular insert of FIG. 2A, because of the material composition of the evaporating pad 150, the absorption level of the cooling water along the pad is very irregular, as it varies along different areas of the evaporating pad 150.

As best shown in the a cross-sectional view of FIG. 2B, the humidity sensor 212A and/or temperature sensor 212B are implemented along the first monitoring band 226 of the evaporating pad 150 while humidity sensor 214A and/or temperature sensor 214B are implemented along the second monitoring band 228 to report relative humidity and temperature data to the monitoring controller 500. The implementation of humidity sensors 212A, 214A and/or temperature sensors 212B, 214B along the respective monitoring bands 226, 228 involves positioning the sensors at a predefined distance away from the evaporating pad 150, surface so as not contact the pad 150. For further clarity, the evaporating pad 150 being associated with humidity sensors 212A, 214A and/or temperature sensors 212B may be defined, in some embodiments, as a positioning of the humidity sensors 212A, 214A and/or the temperature sensors 212B proximate to, but not in contact with, the evaporating pad 150. In some other embodiments, the evaporating pad 150 being associated with the humidity sensors 212A, 214A and/or the temperature sensors 212B may be defined as an incorporation of the humidity sensors 212A, 214A and/or the temperature sensors 212B within the evaporating pad 150.

In this manner, the monitoring controller 500 is able to accurately monitor the relative humidity and temperature levels across the first and second monitoring bands 226, 228 in order to optimally control the application of cooling water to the evaporating pad 150 and virtually prevent any leakages dripping from the bottom of the evaporating pad 150.

FIG. 2A also references that evaporative cooling water distribution arrangement 200 employs certain operations, such as pump control and monitoring/alert messaging as well as utilizes operational metrics, such as target volume flow V_{op-target}, Vₘᵢₙ, Vₘₐₓ, T_{mid}, T_{low-up}, and T_{low-down}. The T_{mid}, T_{low-up}, and T_{low-down} metrics may be a constant or a function of the outside humidity f(RH) and/or temperature levels f(T). Additionally, the distribution arrangement 200 further utilizes a theoretical target volume V_{theo-target} that has been derived from empirical data analyzed by the developers based on the outside relative humidity and/or outside temperature levels. These operational and theoretical metrics are utilized by the monitoring controller 500 to optimally control the application of cooling water to the evaporating pad 150. Accordingly, an operational target volume V_{op-target} of the evaporative cooling water to be applied to the evaporating pad 150 may be formulated as a function of the outside relative humidity before the evaporative cooling pad (V_{target}=f(RH)) and/or outside temperature levels before the cooling pad (V_{target}=f(T)) relative to a given heat load of the heat source 110 (i.e., processing servers 112A-C).

For purposes of clarity and tractability, the operational target volume V_{op-target} of the evaporative cooling water will be described in terms of the detected temperature levels (V_{target}=f(T)). However, it should be appreciated that such temperature level descriptions equally apply to the utilization of detected relative humidity levels or a combination of both.

As such, the operational and theoretical metrics to be utilized by the monitoring controller 500 to execute relevant control processes for evaporative cooling water distribution arrangement 200, are defined as follows. First, the detected outside temperature along the first monitoring band 226 is represented as T_{mid} while target temperature T_{mid-target} relates to either a predetermined constant temperature value or a function of the outside temperature indicated as inlet temperature Ti. The detected outside temperature along the second monitoring band 228 is represented as T_{low} having temperature levels that range from T_{low-down(min)} to T_{low-up(max)}, both of which are functions of the inlet temperature Ti. Also, the minimum evaporative cooling water flow rate is represented as Vₘᵢₙ which constitutes a percentage of the theoretical target volume V_{theo-target} and the maximum evaporative cooling water flow rate is represented as Vₘₐₓ which constitutes a higher percentage of the theoretical target volume V_{theo-target}.

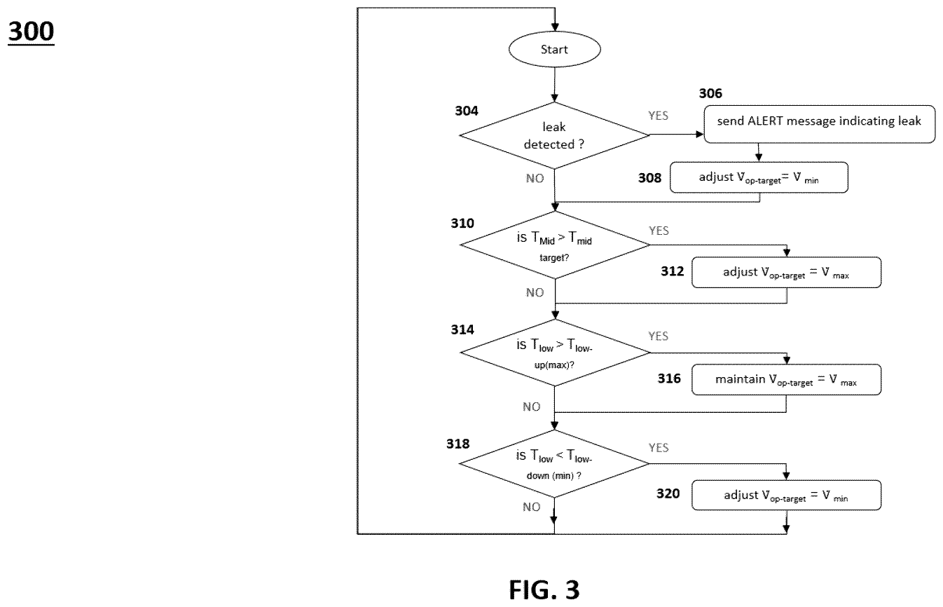

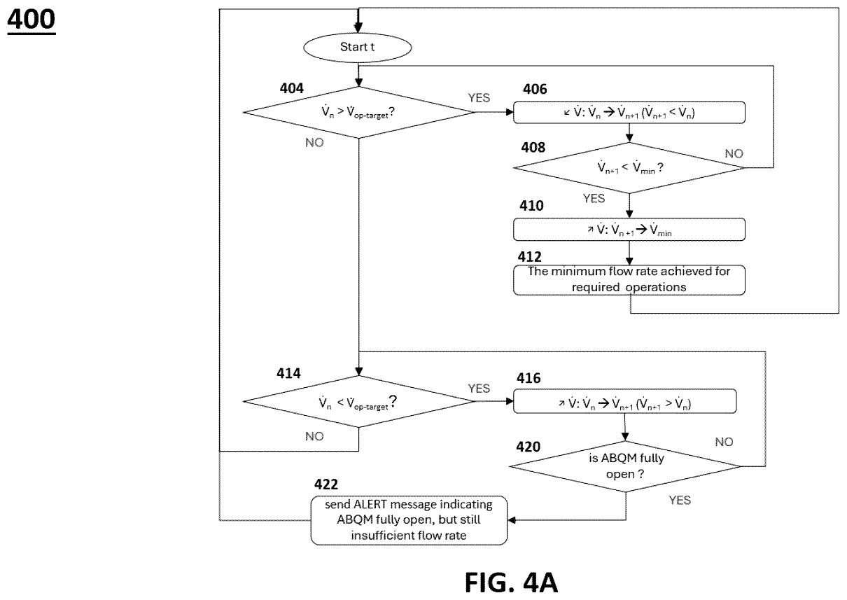

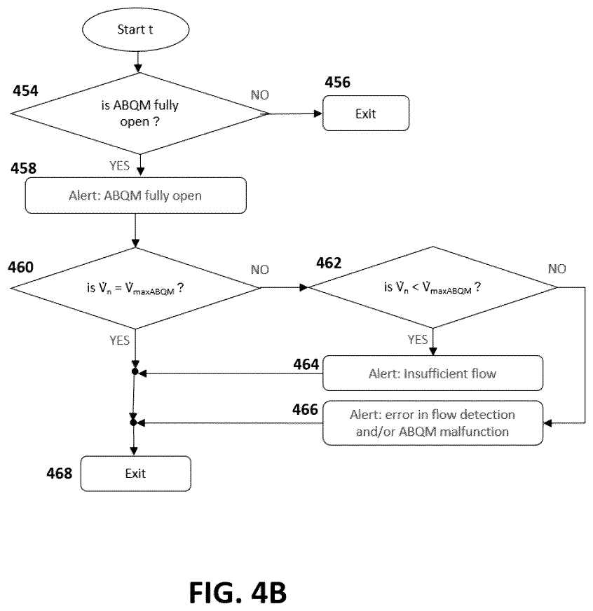

Armed with the noted operational and theoretical metrics, the control operations of monitoring controller 500 to execute the various processes of evaporative cooling water distribution arrangement 200 are described in detail relative to FIGS. 3, 4A, 4B, in accordance with non-limiting embodiments of the present technology.

To begin with, FIG. 3 illustrates a functional flow diagram providing processing operations 300 directed to adjusting the volume flow of the evaporative cooling water based on detected temperature values for the evaporative cooling water distribution arrangement 200 of FIG. 2A, in accordance with non-limiting embodiments of the present technology.

Process 300 commences with step 304 which determines whether a leak has been detected by a sensor disposed in the retention tray 240 located at the bottom of the heat exchanger 20. The sensor may comprise a water sensor, a level sensor, or any kind of sensor capable of detecting the presence of water in pan 240. In the event that a leak has been detected, the monitoring controller 500 transmits an alert message at step 306 and subsequently adjusts the operational volume flow V_{op-target} to Vₘᵢₙ at step 308.

If no leak has been detected, process 300 determines, at step 310, whether the T_{mid} detected temperature is greater than T_{mid-target}. As noted above, the target temperature T_{mid-target} metric value is based on a predetermined constant temperature value or as a function of the outside inlet temperature Tᵢ. Therefore, if the detected T_{mid} temperature value is greater that T_{mid-target}, the operational volume flow V_{op-target} is adjusted to the Vₘₐₓ level at step 312. And, if not, process 300 advances to step 314.

At step 314, process 300 determines whether the detected T_{low} temperature is greater than the T_{low-up(max)}. As noted above, the T_{low-up(max)} metric value is determined as a function of the outside inlet temperature Tᵢ. Therefore, if the detected T_{low} temperature is greater than the T_{low-up(max)}, at step 316, the operational volume flow V_{op-target} is maintained at the Vₘₐₓ level and, if not, process 300 progresses to step 318.

At step 318, process 300 determines whether the detected T_{low} temperature is less than the T_{low-down(min)} metric value. As also noted above, the T_{low-down(min)} metric value is determined as a function of the outside inlet temperature Tᵢ. As such, if the detected T_{low} temperature is less than the T_{low-up(min)}, at step 320, the operational volume flow V_{op-target} is adjusted to the Vₘᵢₙ level.

After step 320, process 300 returns back to the beginning to repeat the volume flow processing cycle. It will be appreciated that process 300 may be performed upon installation and may repeated continuously, at predetermined intervals, or upon detection of an anomaly.

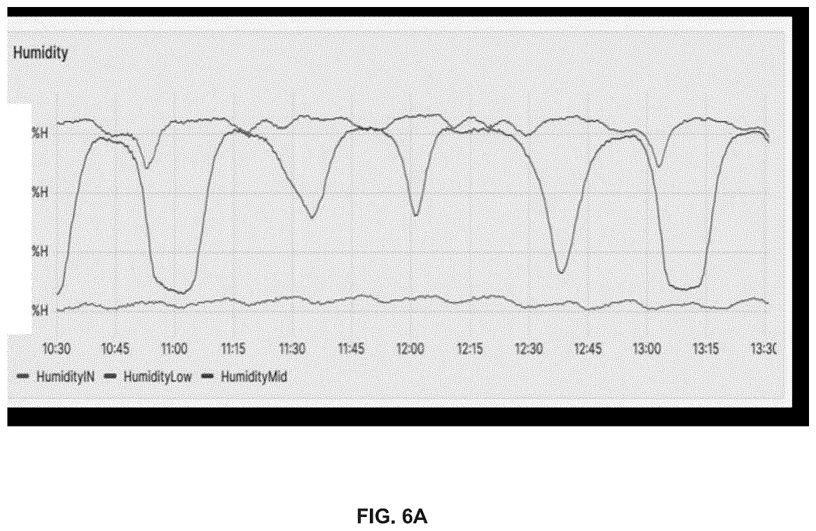

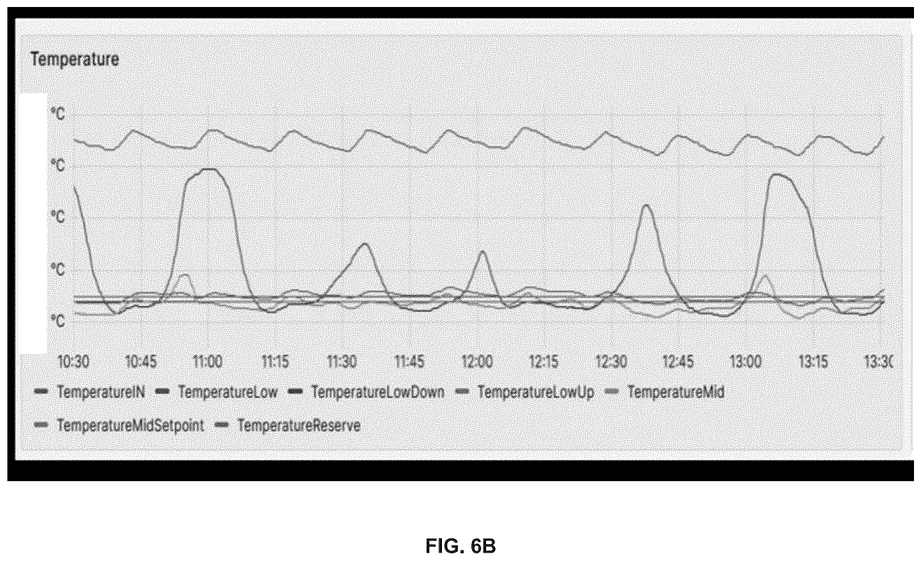

By way of illustration, the graphs presented in FIGS. 6A and 6B indicate the patterns of the temperature and humidity levels in the first and second monitoring bands 226, 228 as a result of the operations of process 300. For example, in the first band 226, there is a constant mid-range temperature (i.e., “TemperatureMid” in FIG. 6B) and a constant mid-range relative humidity level (i.e, “HumidityMid” in FIG. 6A). In the second band 228, at the end of the cooling phase, there is a sinusoidal pattern where the temperature oscillates between low and high values (i.e., wet and dry cycles: “TemperatureLow”), and the humidity oscillates between high and low relative humidity levels (i.e., wet and dry cycles: “HumidityLow”).

FIG. 4A illustrates a functional flow diagram providing processing operations 400 directed to controlling a volume flow valve 208 of the evaporative cooling water distribution arrangement 200 of FIG. 2A for providing a measured cooling water volume flow to the evaporating pad 150, in accordance with non-limiting embodiments of the present technology. As noted above, the volume flow valve 208 may comprise a solenoid-controlled valve, a pressure independent control valve (PICV), or an automatic balancing pressure control valve (ABQM). For purposes of tractability, FIG. 4A refers to an ABQM valve which, should not in anyway, be interpreted as being limiting.

Process 400 commences with step 404 which determines whether the detected flow rate Vₙ is greater than the recommended operational volume flow V_{op-target}. If so, at step 406, the detected flow rate Vₙ is reduced to a flow rate Vₙ₊₁ that is less than the detected flow rate Vₙ. Then at step 408, it is determined whether the reduced flow rate Vₙ₊₁ is less than Vₘᵢₙ and, if not, process 400 returns back to step 404 to recheck whether the detected flow rate Vₙ is still greater than the recommended operational volume flow V_{op-target} and keeps iterating until flow rate Vₙ₊₁ is less than Vₘᵢₙ And, upon the reduced flow rate Vₙ₊₁ reaching a volume level that is less than Vₘᵢₙ then, at step 410, the flow rate Vₙ₊₁ is adjusted to the minimum flow rate Vₘᵢₙ. And, at step 412, it is confirmed that the minimum volume flow rate Vₘᵢₙ has been reached to comply with required operations. Process 400 then returns back to the beginning to repeat the entire volume flow valve 208 control processing cycle.

If back at step 404, it is determined that the detected flow rate Vₙ is not greater than the recommended volume flow rate V_{target}, then step 414 determines whether Vₙ is less than V_{target}. If not, the determination is made that Vₙ is equal to V_{target}, and process 400 returns back to the beginning to repeat the entire volume flow valve 208 control processing cycle. If Vₙ is determined to be less than V_{target}, then process 400 progresses to step 416.

At step 416, the detected flow rate Vₙ is increased to a flow rate Vₙ₊₁ that is greater than the detected flow rate Vₙ. Then, at step 420, process 400 determines whether the volume flow valve 208 is fully open and, if not, the process returns back to step 414 to repeat the checking of whether the detected flow rate is less than operational volume flow V_{op-target}. However, if at step 420 it is determined that the volume flow valve 208 is fully open, then process 400 at step 422, forwards a warning message indicating that the volume flow valve 208 is fully open but there exists an insufficient flow rate. This message is provided to indicate that there may be a water supply, pump, and/or piping issue preventing the required flow rate for proper operations. Accordingly, process 400 returns back to the beginning to repeat the entire volume flow valve 208 control processing cycle. It will be appreciated that process 400 may be performed upon installation and may repeated continuously, at predetermined intervals, or upon detection of an anomaly.

FIG. 4B illustrates a functional flow diagram providing processing operations 450 directed to monitoring the evaporative cooling flow rate after fully opening the volume flow valve 208 to determine any flow rate issues, in accordance with non-limiting embodiments of the present technology. Again, for purposes of tractability, FIG. 4B refers to an ABQM valve which, should not in anyway, be interpreted as being limiting.

Process 450 commences at step 454, to determine whether the volume flow valve 208 has been fully opened. If not, process 450 is exited at step 456. However, if the volume flow valve 208 has been fully opened, process 450 progresses to step 458 to send an alert message indicating that the volume flow valve 208 is fully open.

Then, at step 460, process 450 determines whether the detected flow rate Vₙ is equal to a maximum flow rate that can be accommodated by the volume flow valve V_{maxABQM}. And, if so, process 450 is exited at step 468.

However, if the detected flow rate Vₙ is not equal to the maximum flow rate V_{maxABQM}, then at step 462, process 450 determines if the detected flow rate Vₙ is less than the maximum flow rate V_{maxABQM}. If so, an alert message is sent indicating the condition of insufficient flow rate that requires investigation at step 464 and process 450 is exited at step 468.

If the detected flow rate Vₙ is not less than the maximum flow rate V_{maxABQM}, which indicates that Vₙ is greater than the maximum flow rate V_{maxABQM}, then at step 466, process 450 sends an alert message indicating the condition of an error in detected flow rate Vₙ detection and/or volume flow valve 208 malfunction that requires investigation and process 450 is exited at step 468. It will be appreciated that process 450 may be performed upon installation and may repeated continuously, at predetermined intervals, or upon detection of an anomaly.

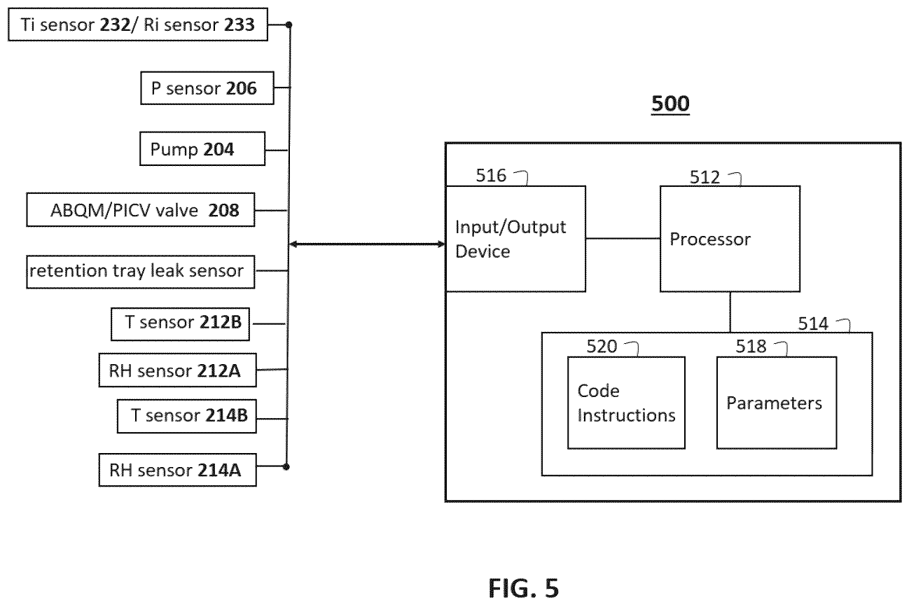

FIG. 5 illustrates a functional block diagram of monitoring controller 500 configured to execute the processing operations noted above, in accordance with an embodiment of the present technology.

As shown, the controller 500 comprises a processor or a plurality of cooperating processors (represented as a processor 512 for simplicity), a memory device or a plurality of memory devices (represented as a memory device 514 for simplicity), one or more input devices and one or more output devices, the input devices and the output devices being possibly combined in one or more input/output devices (represented as a single input/output device 516 for simplicity). The processor 512 is operatively connected to the memory device 514 and to the input/output device 516. The memory device is configured to store a list 518 of relevant parameters. The memory device 514 may comprise a non-transitory computer-readable media for storing control logic instructions 520 that are executable by the processor 512 and, in particular, the executing process 300 for optimally controlling the application of cooling water to the evaporating pad 150.

The processor 512 is communicatively coupled, via the input/output interface 516, to the inlet temperature sensor 232 and inlet humidity sensor 233, pressure sensor 206, pump 204, temperature sensors 212B, 214B, relative humidity sensors 212A, 214A for extraction of relevant data as well as operatively coupled to ABQM/PICV valve 208 and pressure sensor 206 for adjustment and control of disclosed elements. The processor 512 is configured to execute the control logic instructions 520 stored in the memory device 514 to implement the various above-described functions of the controller 500.

It will be appreciated that in certain embodiments, the control logic instructions 520 of processor 512 may be further configured to evaluate the detected data received from the various temperature and humidity sensors noted above over a period of time to provide predictive and/or recommended operating control parameters of operatively coupled elements such as valve 208 and pump 204. As such, the control logic instructions 520 may incorporate artificial intelligence (AI) methodologies that analyze the operational parameters of all detected sensors over time to provide adjustments/control of related elements to optimize evaporative water cooling operations based on empirical/historical data, such as, for example, time of day, weekdays, weekends, different seasons, etc.

With this said, the disclosed non-limiting embodiments provide an evaporative cooling water arrangement for a datacenter dry cooler unit that is configured to optimally control the application of cooling water to evaporating pads and virtually prevents any cooling water leakages while, at the same time, substantially reducing the number of sensors, detectors, hardware, valves, and electronic components required to achieve the intended effect by prior art configurations. And, furthermore, the cooling water arrangement promotes efficient water usage by minimizing wasted water.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A datacenter dry cooling method for cooling a heat-generating electronic processing source, the datacenter associated with a dry cooler unit that incorporates an air-to-liquid heat exchanger panel, an evaporating pad, and an evaporating cooling water distribution arrangement for applying cooling water to the evaporating pad, the method comprising:
at an air outlet surface of the evaporating pad, detecting temperature levels by at least one temperature sensor and/or at least one relative humidity sensor for detecting humidity levels;
at an air inlet surface of the evaporating pad, detecting temperature levels by at least one temperature sensor and/or humidity levels by a relative humidity sensor;
detecting a leak from the evaporating pad by at least one sensor; and
a controller communicatively-coupled to the temperature and humidity levels sensors disposed at the air outlet and air inlet surfaces of the evaporating pad, the leak sensor, and the evaporating cooling water distribution arrangement, in which the controller is configured to execute instructions for:
receiving the detected temperature and humidity levels from the sensors disposed at the air outlet and air inlet surfaces of the evaporating pad and the leak sensor;
determining whether a first detected temperature level (T_{mid}) from the air outlet surface is greater than a predetermined first threshold temperature value (T_{midtarget}) (st. 310) and, upon determining that the detected first temperature level is greater than the first threshold temperature value, adjusting a predetermined target volume flow rate (V_{target}) of the evaporating cooling water distribution arrangement to a predetermined maximum flow rate (Vₘₐₓ);
determining whether a second detected temperature level from the air outlet surface (T_{low}) is greater than a second threshold temperature value (T_{lowupmax}) and, upon determining that the detected temperature level is greater than the second threshold temperature value, adjusting the predetermined the target volume flow rate (V_{target}) of the evaporating cooling water distribution arrangement to the predetermined maximum flow rate (Vₘₐₓ); and
determining whether the second detected temperature level (T_{low}) is less than a third threshold temperature value (T_{lowdownmin}) and, upon determining that the second detected temperature level is less than the third threshold temperature value, adjusting the predetermined the target volume flow rate (V_{target}) of the evaporating cooling water distribution arrangement to a predetermined minimum flow rate (Vₘᵢₙ).

2. The dry cooling method of claim 1, further comprising:
determining whether a leak has been detected;
upon determining that a leak has been detected, sending an alert message indicating the detection of a leak; and
adjusting a predetermined target volume flow rate (Vₘₐₓ) of the evaporating cooling water distribution arrangement to the predetermined minimum flow rate (Vₘᵢₙ).

3. The dry cooling method of claim 1, wherein:
a first temperature and/or humidity sensor is disposed along a first monitoring band on the air outlet surface of the evaporating pad to provide the first detected temperature level (T_{mid}); and
a second temperature and/or humidity sensor disposed along a second monitoring band on the air outlet surface of the evaporating pad to provide the second detected temperature level (T_{low}),
wherein the second monitoring band is positioned lower than the first monitoring band.

4. The dry cooling method of claim 3, wherein:
the determining that the first detected temperature level (T_{mid}) is greater than the first threshold temperature value (T_{midtarget}) corresponds to the temperature level detected by the first temperature sensor along the first monitoring band; and
the determining that the second detected temperature level (T_{low}) is greater than the second threshold temperature value (T_{lowupmax}) or less than the third threshold temperature value (T_{lowdownmin}) corresponds to the temperature level detected by the second temperature sensor along the second monitoring band.

5. The dry cooling method of claim 1, wherein:
the predetermined first threshold temperature value (T_{midtarget}) is based on an empirically-derived constant or an empirically-derived function dependent on the detected temperature level at the air inlet surface of the evaporating pad (Tᵢ); and
the second threshold temperature value (T_{lowupmax}), the third threshold temperature value (T_{lowdownmin}), the predetermined minimum flow rate (Vₘᵢₙ), and the predetermined maximum flow rate (Vₘₐₓ) are based on the empirically-derived function dependent on the detected temperature level (Tᵢ) or humidity level (Rᵢ) at the air inlet surface.

6. The dry cooling method of claim 1, further comprising controlling a volume flow valve of the evaporative cooling water distribution arrangement for applying a controlled measured flow rate of the cooling water to the evaporating pad, by:
determining whether a detected flow rate (Vₙ) is greater than the recommended volume flow rate (V_{target}) and, upon determining that the detected flow rate (Vₙ) is greater than the recommended volume flow rate (V_{target}), adjusting the volume flow rate to a reduced level (Vₙ₊₁) that is less than the detected flow rate (Vₙ);
determining whether the reduced volume flow rate (Vₙ₊₁) is less than the predetermined minimum flow rate (Vₘᵢₙ) and, upon determining that the reduced volume flow rate (Vₙ₊₁) is less than the predetermined minimum flow rate (Vₘᵢₙ), adjusting the volume flow rate to the predetermined minimum flow rate (Vₘᵢₙ);
determining whether the detected flow rate (Vₙ) is less than the recommended volume flow rate (V_{target}) and, upon determining that the detected flow rate (Vₙ) is less than the recommended volume flow rate (V_{target}), adjusting the volume flow rate to an increased level (Vₙ₊₁) that is greater than the detected flow rate (Vₙ);
determining whether the increased volume flow rate level (Vₙ₊₁) results in an opened state of the volume flow valve and, upon determining that the volume flow valve is in an open state, send an alert message indicating that the volume flow valve is in an open state but there exists an insufficient flow rate.

7. The dry cooling method of claim 6, wherein the volume flow valve comprises a solenoid-controlled valve, a pressure independent control valve (PICV), or an automatic balancing pressure control valve (ABQM).

8. The dry cooling method of claim 1, further comprises monitoring whether, after fully opening the volume flow valve, any flow rate issues of the cooling water to be applied to the evaporating pad exist, by:
determining whether the volume flow valve is in the fully open state and, upon determining that the volume flow valve is in the fully open state, send an alert message indicating that the volume flow valve is fully open; and
determining whether the detected flow rate Vₙ is equal to a maximum flow rate of the volume flow valve V_{maxABQM} and, upon determining that the detected flow rate Vₙ is not equal to the valve maximum flow rate V_{maxABQM}, determine whether the detected flow rate Vₙ is less than the valve maximum flow rate V_{maxABQM}, and upon determining that the detected flow rate Vₙ is less than the valve maximum flow rate V_{maxABQM}, sending an alert message indicating the detection of insufficient evaporative cooling water flow,
wherein, upon determining that the detected flow rate Vₙ is not less than the valve maximum flow rate V_{maxABQM}, sending an alert message indicating the detection of a malfunction in flow detection and/or the volume flow valve operations.

9. The dry cooling method of claim 8, wherein, upon determining that the volume flow valve is not in the fully open state, exiting the monitoring process.

10. The dry cooling method of claim 8, further comprising, upon determining that the detected flow rate Vₙ is equal to the valve maximum flow rate V_{maxABQM}, exiting the monitoring process.

11. The dry cooling method of claim 1, wherein the method may be executed to operate at initial installation, to operate continuously, to operate periodically at predetermined intervals, and/or to operate upon detection of an anomaly.

12. A datacenter dry cooling system for cooling a heat-generating electronic processing source, the datacenter associated with a dry cooler unit that incorporates an air-to-liquid heat exchanger panel, an evaporating pad, and an evaporating cooling water distribution arrangement for applying cooling water to the evaporating pad, the system comprising:
at an air outlet surface of the evaporating pad, at least one temperature sensor configured to detect temperature levels and/or at least one relative humidity sensor configured to detect humidity levels;
at an air inlet surface of the evaporating pad, at least one temperature sensor configured to detect temperature levels by and/or a relative humidity sensor configured to detect humidity levels by a relative humidity sensor;
at least one sensor configured to detect a leak from the evaporating pad; and
a controller communicatively-coupled to the temperature and humidity levels sensors disposed at the air outlet and air inlet surfaces of the evaporating pad, the leak sensor, and the evaporating cooling water distribution arrangement, the controller comprising at least one processor configured to:
receive the detected temperature and humidity levels from the sensors disposed at the air outlet and air inlet surfaces of the evaporating pad and the leak sensor;
determine whether a first detected temperature level (T_{mid}) from the air outlet surface is greater than a predetermined first threshold temperature value (T_{midtarget}) (st. 310) and, upon determining that the detected first temperature level is greater than the first threshold temperature value, adjusting a predetermined target volume flow rate (V_{target}) of the evaporating cooling water distribution arrangement to a predetermined maximum flow rate (Vₘₐₓ);
determine whether a second detected temperature level from the air outlet surface (T_{low}) is greater than a second threshold temperature value (T_{lowupmax}) and, upon determining that the detected temperature level is greater than the second threshold temperature value, adjusting the predetermined the target volume flow rate (V_{target}) of the evaporating cooling water distribution arrangement to the predetermined maximum flow rate (Vₘₐₓ); and
determine whether the second detected temperature level (T_{low}) is less than a third threshold temperature value (T_{lowdownmin}) and, upon determining that the second detected temperature level is less than the third threshold temperature value, adjusting the predetermined the target volume flow rate (V_{target}) of the evaporating cooling water distribution arrangement to a predetermined minimum flow rate (Vₘᵢₙ).

13. The dry cooling system of claim 12, the at least one processor being further configured to:
determine whether a leak has been detected;
upon determining that a leak has been detected, send an alert message indicating the detection of a leak; and
adjust a predetermined target volume flow rate (Vₘₐₓ) of the evaporating cooling water distribution arrangement to the predetermined minimum flow rate (Vₘᵢₙ).

14. The dry cooling system of claim 12, wherein:
a first temperature and/or humidity sensor is disposed along a first monitoring band on the air outlet surface of the evaporating pad to provide the first detected temperature level (T_{mid}); and
a second temperature and/or humidity sensor disposed along a second monitoring band on the air outlet surface of the evaporating pad to provide the second detected temperature level (T_{low}),
wherein the second monitoring band is positioned lower than the first monitoring band.

15. The dry cooling system of claim 14, wherein:
the determining that the first detected temperature level (T_{mid}) is greater than the first threshold temperature value (T_{midtarget}) corresponds to the temperature level detected by the first temperature sensor along the first monitoring band; and
the determining that the second detected temperature level (T_{low}) is greater than the second threshold temperature value (T_{lowupmax}) or less than the third threshold temperature value (T_{lowdownmin}) corresponds to the temperature level detected by the second temperature sensor along the second monitoring band.

16. The dry cooling system of claim 12, wherein:
the predetermined first threshold temperature value (T_{midtarget}) is based on an empirically-derived constant or an empirically-derived function dependent on the detected temperature level at the air inlet surface of the evaporating pad (Tᵢ); and
the second threshold temperature value (T_{lowupmax}), the third threshold temperature value (T_{lowdownmin}), the predetermined minimum flow rate (Vₘᵢₙ), and the predetermined maximum flow rate (Vₘₐₓ) are based on the empirically-derived function dependent on the detected temperature level (Tᵢ) or humidity level (Rᵢ) at the air inlet surface.

17. The dry cooling system of claim 12, the at least one processor being configured to control a volume flow valve of the evaporative cooling water distribution arrangement to apply a controlled measured flow rate of the cooling water to the evaporating pad, by the processor being configured to:
determine whether a detected flow rate (Vₙ) is greater than the recommended volume flow rate (V_{target}) and, upon determining that the detected flow rate (Vₙ) is greater than the recommended volume flow rate (V_{target}), adjusting the volume flow rate to a reduced level (Vₙ₊₁) that is less than the detected flow rate (Vₙ);
determine whether the reduced volume flow rate (Vₙ₊₁) is less than the predetermined minimum flow rate (Vₘᵢₙ) and, upon determining that the reduced volume flow rate (Vₙ₊₁) is less than the predetermined minimum flow rate (Vₘᵢₙ), adjusting the volume flow rate to the predetermined minimum flow rate (Vₘᵢₙ);
determine whether the detected flow rate (Vₙ) is less than the recommended volume flow rate (V_{target}) and, upon determining that the detected flow rate (Vₙ) is less than the recommended volume flow rate (V_{target}), adjusting the volume flow rate to an increased level (Vₙ₊₁) that is greater than the detected flow rate (Vₙ);
determine whether the increased volume flow rate level (Vₙ₊₁) results in an opened state of the volume flow valve and, upon determining that the volume flow valve is in an open state, send an alert message indicating that the volume flow valve is in an open state but there exists an insufficient flow rate.

18. The dry cooling system of claim 17, wherein the volume flow valve comprises a solenoid-controlled valve, a pressure independent control valve (PICV), or an automatic balancing pressure control valve (ABQM).

19. The dry cooling system of claim 12, the at least one processor being further configured to monitor whether, after fully opening the volume flow valve, any flow rate issues of the cooling water to be applied to the evaporating pad exist, by the processor being configured to:
determine whether the volume flow valve is in the fully open state and, upon determining that the volume flow valve is in the fully open state, send an alert message indicating that the volume flow valve is fully open; and
determine whether the detected flow rate Vₙ is equal to a maximum flow rate of the volume flow valve V_{maxABQM} and, upon determining that the detected flow rate Vₙ is not equal to the valve maximum flow rate V_{maxABQM}, determine whether the detected flow rate Vₙ is less than the valve maximum flow rate V_{maxABQM}, and upon determining that the detected flow rate Vₙ is less than the valve maximum flow rate V_{maxABQM}, sending an alert message indicating the detection of insufficient evaporative cooling water flow,
wherein, upon determining that the detected flow rate Vₙ is not less than the valve maximum flow rate V_{maxABQM}, send an alert message indicating the detection of a malfunction in flow detection and/or the volume flow valve operations.

20. A non-transitory computer-readable medium comprising computer-executable instructions that, when executed by at least one processor, causes the at least one processor to execute a datacenter dry cooling method for cooling a heat-generating electronic processing source, the method comprising:
receiving detected temperature and humidity levels from sensors disposed at air outlet and air inlet surfaces of an evaporating pad of a dry cooler unit that incorporates an air-to-liquid heat exchanger panel, the evaporating pad, and an evaporating cooling water distribution arrangement for applying cooling water to the evaporating pad;
determining whether a first detected temperature level from the air outlet surface is greater than a predetermined first threshold temperature value and, upon determining that the detected first detected temperature level is greater than the first threshold temperature value, adjusting a predetermined target volume flow rate of the evaporating cooling water distribution arrangement to a predetermined maximum flow rate;
determining whether a second detected temperature level from the air outlet surface is greater than a second threshold temperature value and, upon determining that the second detected temperature level is greater than the second threshold temperature value, adjusting the predetermined the target volume flow rate of the evaporating cooling water distribution arrangement to the predetermined maximum flow rate; and
determining whether the second detected temperature level is less than a third threshold temperature value and, upon determining that the second detected temperature level is less than the third threshold temperature value, adjusting the predetermined the target volume flow rate of the evaporating cooling water distribution arrangement to a predetermined minimum flow rate.
